(19) United States
(12) Patent Application Publication
(10) Pub. No.: US 2009/0023285 A1
(43) Pub. Date: Jan. 22, 2009

(54) METHOD OF FORMING CONTACT OF SEMICONDUCTOR DEVICE

(75) Inventor: Wan Soo Kim, Seoul (KR)

Correspondence Address: MARSHALL, GERSTEIN & BORUN LLP, 233 S. WACKER DRIVE, SUITE 6300, SEARS TOWER, CHICAGO, IL, 60606, US

(73) Assignee: HYNIX SEMICONDUCTOR INC., Icheon-si (KR)

(21) Appl. No.: 12/126,146

(22) Filed: May 23, 2008

(30) Foreign Application Priority Data
Jul. 16, 2007 (KR) 10-2007-0071039

(51) Int. Cl. H01L 21/4763

(52) U.S. Cl. 438/618; 257/E21.476

(57) ABSTRACT

The present invention relates to a method of forming a contact of a semiconductor device. According to a method of forming a contact of a semiconductor device in accordance with an aspect of the present invention, first and second insulating layers are sequentially formed over a semiconductor substrate. A contact hole is formed by sequentially etching the first and second insulating layers. An aperture portion of the contact hole is widened by etching the second insulating layer. A conductive material is gap-filled over an entire surface including the contact hole, thus forming a contact.

### CROSS-REFERENCES TO RELATED APPLICATION

The priority to Korean patent application number 10-2007-0071039, filed on Jul. 16, 2007, is hereby claimed, and the disclosure thereof is hereby incorporated by reference herein in its entirety.

### BACKGROUND OF THE INVENTION

The present invention relates to a method of forming a contact of a semiconductor device and, more particularly, to a method of forming a contact of a semiconductor device, which can prevent voids from being formed within contacts.

In general, as semiconductor devices are gradually more highly integrated, a distance between the gate electrode and the bit line and a distance between the gate electrode and the storage node are increasingly narrowed. Thus, a contact area with a LPP (Landing Poly Plug) is decreased due to misalignment when a storage node contact is formed, resulting in a high resistance value. There is another problem that process margin of the contact is reduced.

As a solution for increasing this contact margin, a well-known SAC (Self-Aligned Contact) fabrication technology has been used. The SAC process is used to form contact holes by employing the step of peripheral structures and can be used to obtain various sizes of contact holes depending on the height of peripheral structures, the thickness of insulating material in which contact holes will be formed, an etch method, and so on, without using a mask. Accordingly, the SAC process has been used as a method suitable to realize semiconductor devices which gradually become small due to high integration.

A conventional method of forming a contact plug of a semiconductor device is described below with reference to FIG. 1.

FIGS. 1A and 1B are sectional views illustrating a conventional method of forming a contact of a semiconductor device.

Referring to FIG. 1A, gate patterns 11 are formed on a semiconductor substrate 10. An ion implantation process is then performed to thereby form a junction region 12 in the semiconductor substrate 10 adjacent to the gate patterns 11. Spacers 13 are then formed on sidewalls of the gate patterns 11. A SAC passivation layer 14 is formed over the entire surface including the spacers 13. An interlayer dielectric layer 15 is formed over the entire surface.

Referring to FIG. 1B, a contact hole 16 through which the SAC passivation layer 14 is exposed is formed by selectively etching the interlayer dielectric layer 15. A barrier layer 17 is formed over the entire surface including the contact hole 16. A contact 18 is formed over the entire surface including the barrier layer 17.

In the above-described conventional method of forming a contact of a semiconductor device, the higher the degree of integration of devices, the smaller the size of the contact hole 16. Due to this small size, when the barrier layer 17 is deposited, overhang of the barrier layer 17 material occurs in an aperture portion of the contact hole 16. This overhang of the barrier layer 17 material causes a void when the contact hole 16 is gap-filled with a subsequent conductive material, leading to a low yield of devices.

### BRIEF SUMMARY OF THE INVENTION

The present invention is directed towards a method of forming a contact of a semiconductor device, in which first and second insulating layers having different etch rates are sequentially stacked over a semiconductor substrate and a contact hole having a top width wider than a bottom width is then formed using an etch process. The foregoing method can be used to limit or prevent voids from occurring within contacts when the contacts are formed, and therefore the yield of devices can be increased.

A method of forming a contact of a semiconductor device in accordance with an embodiment of the present invention includes forming a junction region by performing an ion implantation process on a semiconductor substrate on which gate patterns are formed, forming a SAC (Self-Aligned Contact) passivation layer over an entire surface including the junction region, sequentially stacking first and second insulating layers over an entire surface including the SAC passivation layer, forming a contact hole through which the SAC passivation layer of the junction region is exposed by etching the first and second insulating layers, widening an aperture portion of the contact hole by etching at least the second insulating layer, forming a slope portion on at least upper sidewalls of the contact hole by performing a dry etch process, forming a barrier layer over an entire surface including the contact hole, exposing the junction region by sequentially etching a bottom surface of the barrier layer and the SAC passivation layer of the junction region, and gap-filling the inside of the contact hole with a conductive material, thus forming a contact.

A wet etch rate of the first insulating layer is higher than that of the second insulating layer. The first insulating layer preferably is formed of a HDP (High Density Plasma) oxide layer. The first insulating layer preferably is formed to a thickness in a range of 5000 to 10000 angstrom.

The second insulating layer preferably is formed using a PE-TEOS (Plasma-Enhanced TetraEthyl OrthoSilicate) oxide layer. The second insulating layer preferably is formed to a thickness in a range of 500 to 1500 angstrom.

The widening of the aperture portion of the contact hole includes etching the second insulating layer, to a preferred thickness in a range of 30 to 100 angstrom, preferably using a wet etch process. The wet etch process preferably is performed using a solution in which distilled water and BOE (Buffered Oxide Etchant) are diluted at a ratio of 100:1.

The dry etch process preferably is performed using a gas CF₄, CHF₃, Ar or O₂, or a mixed gas of any combination of the foregoing. The dry etch process preferably is performed at a pressure in a range of 10 to 100 mT. The dry etch process preferably is performed using power in a range of 100 to 2000 W.

The barrier layer preferably is formed to a thickness in a range of 20 to 40 angstrom.

### BRIEF DESCRIPTION OF THE DRAWINGS

FIGS. 1A and 1B are sectional views illustrating a conventional method of forming a contact of a semiconductor device; and

FIGS. 2A to 2D are sectional views illustrating a method of forming a contact of a semiconductor device in accordance with an embodiment of the present invention.

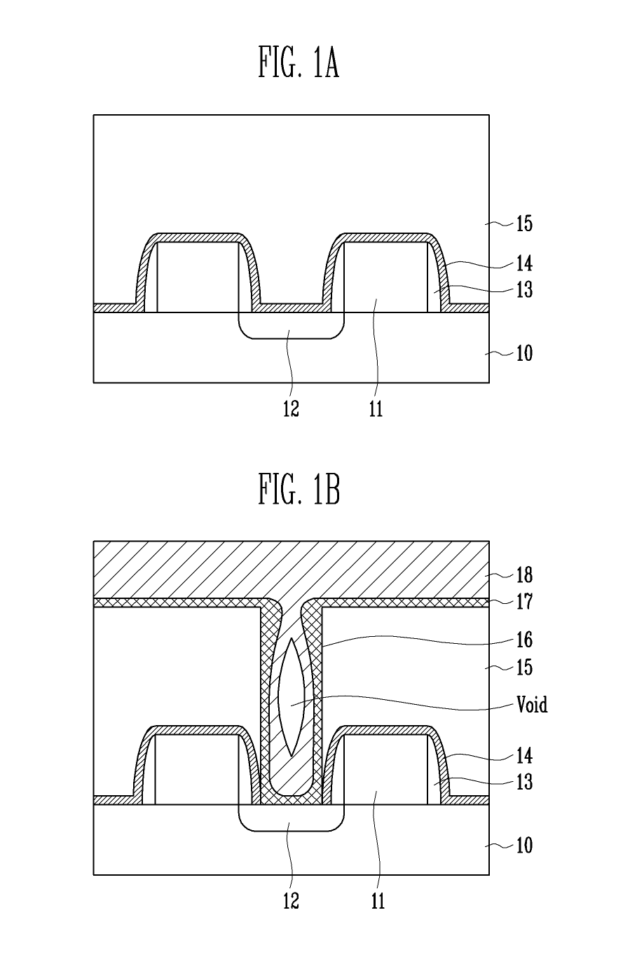

### DESCRIPTION OF SPECIFIC EMBODIMENTS

Now, a specific embodiment according to the present invention will be described with reference to the accompanying drawings. However, the present invention is not limited to the disclosed embodiment, but may be implemented in various manners. The embodiment is provided to complete the disclosure of the present invention and to allow those having ordinary skill in the art to understand the present invention. The present invention is defined by the category of the claims.

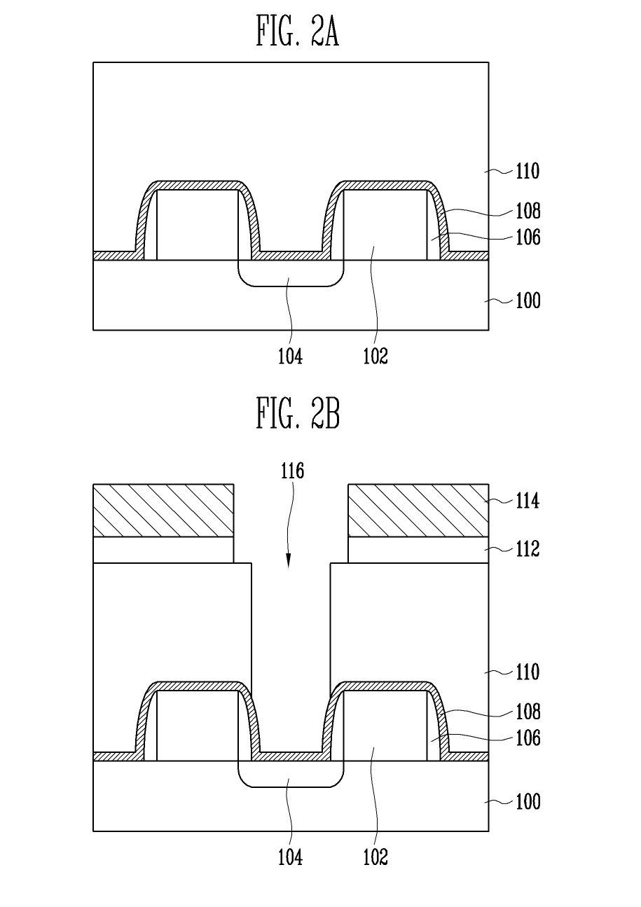

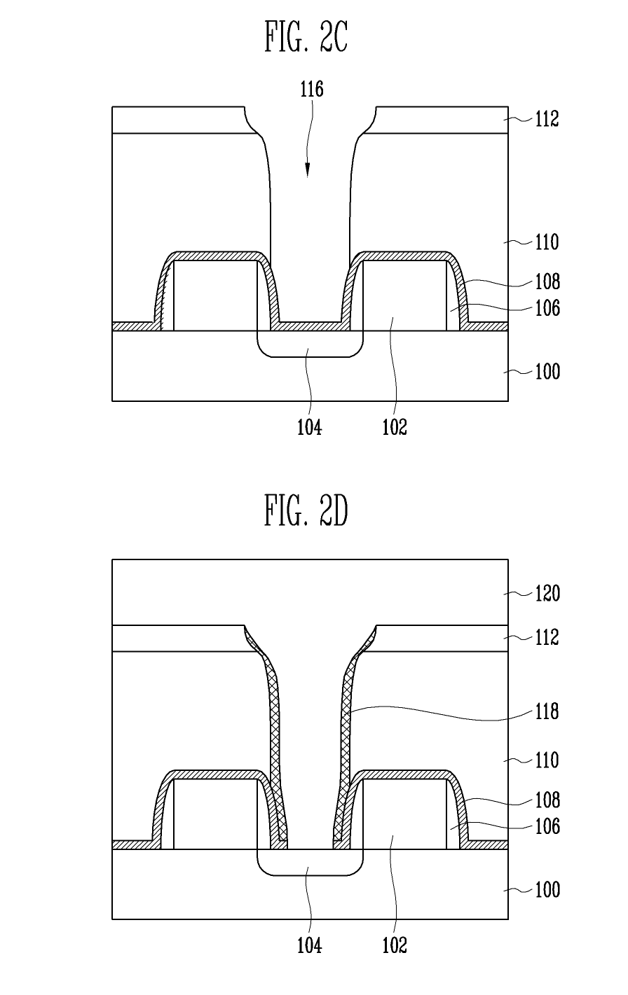

FIGS. 2A to 2D are sectional views illustrating a method of forming a contact of a semiconductor device in accordance with an embodiment of the present invention.

Referring to FIG. 2A, gate patterns 102 are formed on a semiconductor substrate 100. The gate patterns 102 can be formed by stacking a gate dielectric layer and a gate conductive layer and then etching them. An ion implantation process is performed on the semiconductor substrate 100 adjacent to the gate patterns 102, thus forming a junction region 104.

An insulating layer (not shown) is formed over the entire surface including the junction region 104. A dry etch process is then performed to thereby form spacers 106 on sidewalls of the gate patterns 102. A SAC passivation layer 108 is formed over the entire surface including the spacers 106. The SAC passivation layer 108 may be formed of a nitride layer. A first insulating layer 110 is formed over the entire surface including the SAC passivation layer 108. The first insulating layer 110 may be formed to a thickness in a range of 5000 to 10000 angstrom using a HDP (High Density Plasma) oxide layer.

Referring to FIG. 2B, a second insulating layer 112 having an etch rate higher than that of the first insulating layer 110 is formed over the entire surface including the first insulating layer 110. The second insulating layer 112 may be formed to a thickness in a range of 500 to 1500 angstrom using a PE-TEOS (Plasma-Enhanced TetraEthyl OrthoSilicate) oxide layer. A hard mask layer 114 is formed over the entire surface including the second insulating layer 112. The hard mask layer 114 may be formed to a thickness in a range of 2000 to 3000 angstrom using an amorphous carbon layer.

The hard mask layer 114 is patterned, for example by an etch process employing photoresist patterns. The second insulating layer 112 and the first insulating layer 110 are etched to thereby form a contact hole 116 through which the SAC passivation layer 108 formed on the junction region 104 is exposed. The SAC passivation layer 108 functions to prevent damage to the semiconductor substrate 100 in a subsequent etch process.

Referring to FIG. 2C, after the hard mask layer is removed, a wet etch process is carried out in order to increase the size of the contact hole 116. After the wet etch process, an aperture portion of the contact hole 116 is wider than a bottom portion of the contact hole 116 since the etch rate of the second insulating layer 112 is higher than that of the first insulating layer 110. In the wet etch process, the second insulating layer 112 (that is, a target) may be etched to a thickness in a range of 30 to 100 angstrom. Here, the wet etch process may be performed using a solution in which BOE (Buffered Oxide Etchant) is diluted in distilled water, for example at a preferred ratio of distilled water to BOE (Buffered Oxide Etchant) of 100:1.

The sidewalls of the first and second insulating layers 110, 112 are etched by a dry etch process so that at least the upper sidewalls of the contact hole 116 have inclined surfaces. This configuration is for the purpose of increasing the gap-fill effect in a subsequent conductive material gap-fill process. The dry etch process may be formed using a gas CF₄, CHF₃, Ar or O₂, or a mixed gas of any combination of the foregoing. The dry etch process may be performed at a pressure of 10 to 100 mT. The dry etch process may be performed using power in a range of 100 to 2000 W.

Referring to FIG. 2D, a barrier layer 118 is formed over the entire surface including the contact hole 116. The barrier layer 118 material is then removed (e.g., by etching) from the bottom of the contact hole 116, and preferably also from the surface of the second insulating layer 112, thereby leaving barrier layer 118 material only on the sidewalls of the contact hole 116. The SAC nitride layer 108 remaining at the bottom of the barrier layer 118 on the junction region 104 is removed (e.g., by etching) to thereby expose the junction region 104. Conductive material is formed over the entire surface including the barrier layer 118, thus forming a contact 120.

The barrier layer 118 may be formed to a thickness in a range of 20 to 40 angstrom.

In accordance with an embodiment of the present invention, first and second insulating layers having different etch rates are sequentially stacked over a semiconductor substrate and a contact hole having a top width wider than a bottom width is then formed using an etch process. Accordingly, voids can be prevented from occurring within contacts when the contacts are formed and, therefore, the yield of devices can be increased.

The embodiment disclosed herein has been proposed to allow a person skilled in the art to easily implement the present invention. Therefore, the scope of the present invention is not limited by or to the embodiment as described above, and should be construed to be defined only by the appended claims and their equivalents.

What is claimed is:

1. A method of forming a contact of a semiconductor device, the method comprising:
sequentially forming first and second insulating layers over a semiconductor substrate;
forming a contact hole by sequentially etching the first and second insulating layers;
widening an aperture portion of the contact hole by etching at least the second insulating layer; and
gap-filling a conductive material over an entire surface including the contact hole, thus forming a contact.

2. The method of claim 1, wherein a wet etch rate of the second insulating layer is higher than that of the first insulating layer.

3. The method of claim 1, comprising forming the first insulating layer of a HDP (High Density Plasma) oxide layer.

4. The method of claim 1, comprising forming the first insulating layer to a thickness in a range of 5000 to 10000 angstrom.

5. The method of claim 1, comprising forming the second insulating layer of a PE-TEOS (Plasma-Enhanced TetraEthyl OrthoSilicate) oxide layer.

6. The method of claim 1, comprising forming the second insulating layer to a thickness in a range of 500 to 1500 angstrom.

7. The method of claim 1, comprising widening the aperture portion of the contact hole by etching the second insulating layer, as a target, to a thickness in a range of 30 to 100 angstrom using a wet etch process.

8. A method of forming a contact of a semiconductor device, the method comprising:
forming a junction region by performing an ion implantation process on a semiconductor substrate on which gate patterns are formed;
forming a SAC (Self-Aligned Contact) passivation layer over an entire surface including the junction region;
sequentially stacking first and second insulating layers over an entire surface including the SAC passivation layer;
forming a contact hole through which the SAC passivation layer of the junction region is exposed by etching the first and second insulating layers;
widening an aperture portion of the contact hole by etching at least the second insulating layer;
forming a slope portion on at least the upper sidewalls of the contact hole by performing a dry etch process;
forming a barrier layer over an entire surface including the contact hole;
exposing the junction region by sequentially etching a bottom surface of the barrier layer and the SAC passivation layer of the junction region; and
gap-filling the inside of the contact hole with a conductive material, thus forming a contact.

9. The method of claim 8, wherein a wet etch rate of the second insulating layer is higher than that of the first insulating layer.

10. The method of claim 8, comprising forming the first insulating layer of a HDP (High Density Plasma) oxide layer.

11. The method of claim 8, comprising forming the first insulating layer to a thickness in a range of 5000 to 10000 angstrom.

12. The method of claim 8, comprising forming the second insulating layer of a PE-TEOS (Plasma-Enhanced TetraEthyl OrthoSilicate) oxide layer.

13. The method of claim 8, comprising forming the second insulating layer to a thickness in a range of 500 to 1500 angstrom.

14. The method of claim 8, comprising widening the aperture portion of the contact hole by etching the second insulating layer, as a target, to a thickness in a range of 30 to 100 angstrom using a wet etch process.

15. The method of claim 14, comprising performing the wet etch process using a solution in which distilled water and BOE (Buffered Oxide Etchant) are diluted at a ratio of 100:1.

16. The method of claim 8, comprising performing the dry etch process using a gas selected from the group consisting of CF₄, CHF₃, Ar, O₂, and combinations thereof.

17. The method of claim 8, comprising performing the dry etch process at a pressure in a range of 10 to 100 mT.

18. The method of claim 8, comprising performing the dry etch process using power in a range of 100 to 2000 W.

19. The method of claim 8, comprising forming the barrier layer to a thickness in a range of 20 to 40 angstrom.
